(19) United States
(12) Patent Application Publication
(10) Pub. No.: US 2018/0026458 A1
(43) Pub. Date: Jan. 25, 2018

(54) ELECTRIC POWER STORAGE APPARATUS

(71) Applicant: YAZAKI CORPORATION, Tokyo (JP)

(72) Inventor: Yoshihiro KAWAMURA, Makinohara-shi (JP)

(73) Assignee: YAZAKI CORPORATION, Tokyo (JP)

(21) Appl. No.: 15/631,425

(22) Filed: Jun. 23, 2017

(30) Foreign Application Priority Data
Jul. 20, 2016 (JP) 2016-142556

(51) Int. Cl. H02J 7/00; H03K 17/97

(52) U.S. Cl. CPC H02J 7/0031; H02J 7/0036; H03K 17/97

(57) ABSTRACT

A power storage device which receives an electric power from a high-voltage circuit of a vehicle is disposed, and reed switches are disposed in a circuit which switches a connection state of the power storage device. In the reed switches, the ON/OFF state is switched depending on the energization/deenergization and energization direction of a high-voltage bus bar which is placed at a proximal position. Moreover, a permanent magnet which generates a DC magnetic field to apply a bias in a specific direction is placed in the vicinity of the reed switches, and switching according to the energization direction is enabled. A movable permanent magnet is placed in the vicinity of the high-voltage bus bar, and the position of the permanent magnet is changed depending on the energization/deenergization and the energization direction.

### CROSS REFERENCE TO RELATED APPLICATIONS

This application is based on and claims priority from Japanese patent application No. 2016-142556 filed on Jul. 20, 2016, the entire contents of which are incorporated herein by reference.

### BACKGROUND OF THE INVENTION

### 1. Technical Field

The present invention relates to an electric power storage apparatus including a power storage element which can store an electric power supplied from a battery circuit of a vehicle.

### 2. Background Art

In a vehicle such as a hybrid vehicle including an internal combustion engine and an electric motor as a driving source for generating a propulsion force, or an electric vehicle, a high-voltage main battery or the like mounted on the vehicle body is charged, and the propulsive force is generated by using electric energy supplied from the main battery or the like. A power source circuit which generates electric energy for producing a propulsive force for the vehicle, and which is configured by the main battery or the like is often designed so as to handle a high voltage such as about 200 [V] in order to reduce a power loss.

In a vehicle handling a high voltage, it is necessary to protect an occupant or the like from an electric shock due to electric leakage. Therefore, it is usual that a high-voltage circuit is electrically insulated from the ground such as the vehicle body. That is, even when the occupant touches the vehicle body, there is no risk of an electric shock. However, there is a possibility that the insulation resistance between the high-voltage circuit and the ground may be lowered due to deterioration, a failure, a change in the environment such as the humidity, a collision of the vehicle, or the like. When the insulation resistance is lowered, there arises a possibility that the occupant or the like may receive an electric shock.

In a vehicle handling a high voltage, therefore, the insulation resistance between a high-voltage circuit and the ground must be checked periodically or always. For the purpose, an insulated state detection device is used.

In insulated state detection devices disclosed in Patent Literatures JP-A-2013-205082, JP-A-2014-126382, and JP-A-2014-149193, a capacitor which is called a flying capacitor is used, the voltage is measured while repeating cycles of charging and discharging the flying capacitor, and the ground fault resistance is detected based on the measured voltage. In such a measuring apparatus, the voltage is measured after the flying capacitor is charged, and then charges stored in the flying capacitor are discharged. The discharging is an operation which is necessary to correctly perform the measurement in the next measurement cycle.

### SUMMARY

An on-vehicle apparatus such as the conventional insulated state detection devices is provided with a controller for performing the charging and discharging cycles, and measurements in various measuring apparatuses. Such a controller requires a low-voltage circuit for supplying an electric source power from a low-voltage battery of usually 12 [V]. Moreover, a low-voltage battery is usually disposed at a position which is remote from a main battery. Therefore, the low-voltage circuit is laid from the low-voltage battery to the controller which is disposed in the vicinity of the main battery. In the periphery of the main battery, consequently, the low-voltage circuit and a high-voltage circuit coexist. However, the mixed existence of low- and high-voltage circuits is not preferable because of the difference in their voltages, and hence it is desired to isolate a high-voltage circuit and a low-voltage circuit from each other.

The invention has been conducted in view of the above-discussed situations. It is an object of the invention to provide an electric power storage apparatus in which it is not required to, in order to control the operation of the apparatus itself, supply a power source power from a low-voltage circuit, and therefore the low-voltage circuit can be isolated from a high-voltage circuit in the vicinity of a main battery.

In order to attain the object, the electric power storage apparatus of the invention is characterized in (1) to (5) below.

(1) An electric power storage apparatus wherein

the apparatus includes:

a power storage element which can store an electric power supplied from a battery circuit of a vehicle; and

a magnetic switch circuit which can be switched between connection and disconnection states of the battery circuit and the power storage element, and,

when a magnetic field is generated by a current flowing through a high-voltage conducting path that is electrically connected to the battery circuit, the magnetic switch circuit is switched to the connection state.

(2) An electric power storage apparatus wherein

the apparatus includes:

a power storage element which can store an electric power supplied from a battery circuit of a vehicle;

a first magnetic switch circuit which can be switched between connection and disconnection states of the battery circuit and the power storage element; and

a second magnetic switch circuit which can be switched between connection and disconnection states of the power storage element and an external low-voltage circuit,

when one of the first magnetic switch circuit and the second magnetic switch circuit is in the connection state, the other magnetic switch circuit is in the disconnection state, and the connection and disconnection states are switched based on a magnetic field which is generated by a current flowing through a high-voltage conducting path that is electrically connected to the battery circuit.

(3) The electric power storage apparatus according to (2) above, wherein,

in a case of a magnetic field which is generated by a current in a direction along which the current flows into the battery circuit, the first magnetic switch circuit is in the connection state, and the second magnetic switch circuit is in the disconnection state, and,

in a case of a magnetic field which is generated by a current in a direction along which the current flows from the battery circuit, the first magnetic switch circuit is in the disconnection state, and the second magnetic switch circuit is in the connection state.

(4) The electric power storage apparatus according to (2) or (3) above, wherein

the apparatus further includes a magnetic field generating member which is placed in a vicinity of the first and second magnetic switch circuits, and which provides a predetermined DC magnetic field for the first and second magnetic switch circuits, and,

in the first and second magnetic switch circuits, the connection and disconnection states are switched according to a degree of an influence of the DC magnetic field generated by the magnetic field generating member.

(5) The electric power storage apparatus according to any one of (2) to (4) above, wherein

the external low-voltage circuit constitutes a part of a detection circuit for detecting a state relating to the battery circuit, the power storage element is connected to the detection circuit, and

the electric power stored in the power storage element is used for driving the detection circuit.

According to the electric power storage apparatus having the configuration of (1) above, when the magnetic switch circuit is switched so that the battery circuit and the power storage element are in the connection state, charges can be introduced and stored from the high-voltage conducting path into the power storage element. Moreover, the state of the magnetic switch circuit is controlled by the magnetic field due to the current flowing through the high-voltage conducting path. According to the configuration, even when the electric source power is not supplied, the magnetic switch circuit can operate.

According to the electric power storage apparatus having the configuration of (2) above, when the first and second magnetic switch circuits are switched so that the battery circuit and the power storage element are in the connection state, and the power storage element and the external low-voltage circuit are in the disconnection state, charges can be introduced and stored from the high-voltage conducting path into the power storage element. When the first and second magnetic switch circuits are switched so that the battery circuit and the power storage element are in the disconnection state, and the power storage element and the external low-voltage circuit are in the connection state, the power storage element can supply the stored power to the low-voltage circuit. Moreover, the states of the first and second magnetic switch circuits are controlled by the magnetic field due to the current flowing through the high-voltage conducting path. According to the configuration, even when the electric source power is not supplied, the magnetic switch circuits can operate.

According to the electric power storage apparatus having the configuration of (3) above, the position of a magnetic field generating member is switched depending on whether a current flows in the direction along which the battery circuit is charged or not, and the states of the first and second magnetic switch circuits can be switched.

According to the electric power storage apparatus having the configuration of (4) above, the states of the first and second magnetic switch circuits can be switched according to the degree of an influence of the DC magnetic field generated by the magnetic field generating member. Therefore, for example, the connection and disconnection states of the first and second magnetic switch circuits can be switched depending on the composite magnetic field of the magnetic field due to the current flowing through the high-voltage conducting path, and that generated by the magnetic field generating member, or according to the position of the magnetic field generating member.

According to the electric power storage apparatus having the configuration of (5) above, the operating state of the battery circuit can be detected by using the detection circuit. Moreover, the electric source power which is necessary to drive the detection circuit can be generated based on the power stored in the power storage element, and therefore the stored power can be effectively used.

According to the invention, it is possible to provide an electric power storage apparatus in which it is not required to, in order to control the operation of the apparatus itself, supply a power source power from a low-voltage circuit, and therefore the low-voltage circuit can be isolated from a high-voltage circuit in the vicinity of a main battery.

In the above, the invention has been briefly described. When a mode for carrying out the invention (hereinafter, referred to as “embodiment”) which will be described below is through read with reference to the accompanying drawings, the detail of the invention will be further clarified.

### BRIEF DESCRIPTION OF THE DRAWINGS

FIG. 1 is an electrical circuit diagram showing main components of a system including an electric power storage apparatus of an embodiment of the invention.

FIG. 2 is a front view diagrammatically showing Configuration example (1) of the vicinity of a reed switch SW1.

FIG. 3 is a front view diagrammatically showing Configuration example (2) of the vicinity of the reed switch SW1.

FIG. 4 is a front view diagrammatically showing Configuration example (3) of the vicinity of the reed switch SW1.

### DETAILED DESCRIPTION OF EMBODIMENTS

Hereinafter, a specific embodiment of the invention will be described with reference to the drawings.

Firstly, the configuration and operation of the entire embodiment will be summarized.

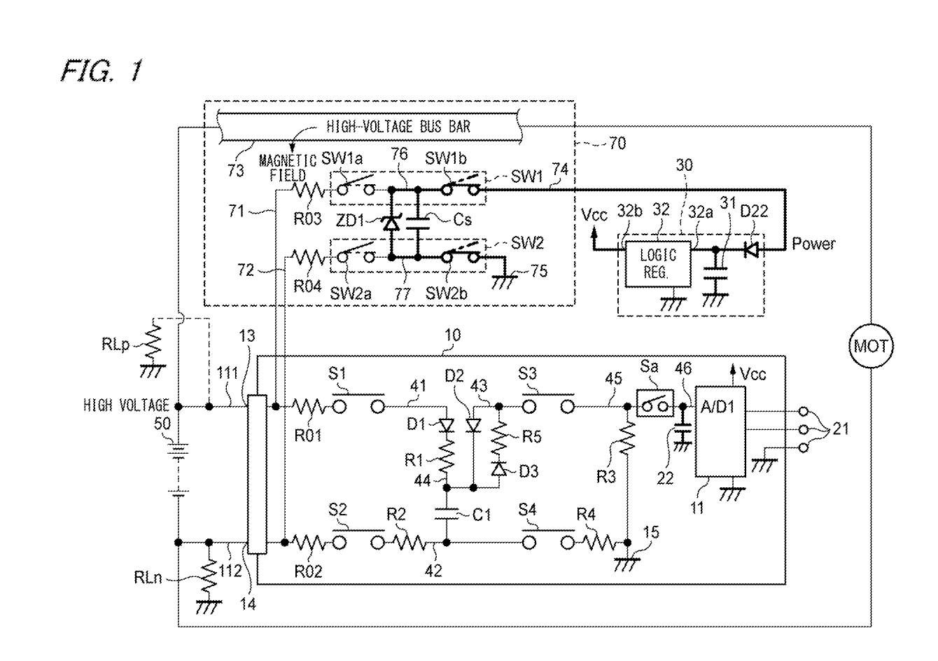

FIG. 1 shows main components of a system including an electric power storage apparatus of the embodiment of the invention. The system shown in FIG. 1 includes a ground fault measurement circuit (detection circuit) 10 which is used for detecting the ground fault resistance on a vehicle, and peripheral circuits which generate an electric source power that is necessary for on-vehicle apparatuses such as the ground fault measurement circuit 10 to operate. The peripheral circuits include the electric power storage apparatus 70.

In the example shown in FIG. 1, it is assumed that the electric power storage apparatus 70 is used for generating an electric source power which is necessary for the ground fault measurement circuit 10 to measure the ground fault resistance. Alternatively, the electric power storage apparatus 70 may be used for generating an electric source power which is required by a voltage measuring apparatus and other on-vehicle apparatuses.

The ground fault measurement circuit 10 shown in FIG. 1 can be used while being mounted on a vehicle such as an electric vehicle or a hybrid vehicle including an internal combustion engine and an electric motor as a driving source for generating a propulsion force. An on-vehicle DC high-voltage power source 50 which functions as a main battery outputs a DC power of a high voltage of, for example, about 200 [V]. The power output from the on-vehicle DC high-voltage power source 50 can drive an electric motor MOT which generates a propulsion force for the vehicle.

The on-vehicle DC high-voltage power source 50 is configured by rechargeable batteries such as lithium-ion batteries, and can store a power of a high voltage of, for example, about 100 to 200 [V]. The on-vehicle DC high-voltage power source 50 can supply as required the DC power to an inverter apparatus connected to the electric motor MOT which generates a propulsion force for the vehicle, and other loads.

The on-vehicle DC high-voltage power source 50 can be connected to the electric motor MOT which can operate as a generator, via the inverter apparatus that has a converter function, or to external equipment. The generator converts the driving force of the engine, an excess kinetic energy during deceleration of the vehicle, and the like to electrical energy, and recovers the energy. The external equipment is a charging facility which is disposed in a place where the vehicle is to be parked, and which is dedicated to a vehicle. When charging is to be performed, the external equipment is connected to the on-vehicle DC high-voltage power source 50 via a detachable external connection cable.

By contrast, a positive power supply line 111 of the output of the on-vehicle DC high-voltage power source 50 is electrically insulated from a ground electrode. Also a negative power supply line 112 is electrically insulated from the ground electrode. The ground electrode corresponds to a grounded portion such as the vehicle body. Here, the insulation state between the positive power supply line 111 and the ground electrode can be indicated by a ground fault resistance RLp, and that between the negative power supply line 112 and the ground electrode can be indicated by a ground fault resistance RLn.

When the ground fault measurement circuit 10 shown in FIG. 1 is mounted on a vehicle, it is possible to monitor the insulation state of the vehicle at any time as required. That is, the ground fault measurement circuit 10 can be used for detecting the ground fault resistances RLp, RLn in the output of the on-vehicle DC high-voltage power source 50 to know the insulation state.

As shown in FIG. 1, therefore, positive and negative input-side terminals 13, 14 of the ground fault measurement circuit 10 are connected to the positive and negative power supply lines 111, 112, respectively.

As shown in FIG. 1, output terminals 21 are disposed in order to output the result of a measurement by the ground fault measurement circuit 10, and information of alarm. The output terminals 21 can be connected, for example, to an electronic control unit (ECU) of the vehicle.

In the system shown in FIG. 1, a power source unit 30 is disposed in order to generate a logic DC power supply voltage Vcc which is necessary for the ground fault measurement circuit 10 to operate. A diode D22 which is connected to the input of the power source unit 30 is connected to the output of the electric power storage apparatus 70. The diode D22 has a function of preventing a reverse current flow from occurring.

One end of a capacitor 31 in the power source unit 30 is connected to the cathode terminal of the diode D22, and also to an input terminal 32a of a regulator 32, and the other end is connected to the ground. The capacitor 31 stores charges which are supplied via the diode D22, so as to be used as an electric source power. The regulator 32 has a function of voltage regulation in which a DC voltage is stably generated based on an input power, and outputs the predetermined logic DC power supply voltage Vcc which is necessary as the electric source power for various logic circuits, from an output terminal 32b. Specifically, the regulator outputs a DC voltage of about +5 [V] or +3.3 [V] as the logic DC power supply voltage Vcc.

Next, a configuration example of the electric power storage apparatus 70 will be described.

The electric power storage apparatus 70 shown in FIG. 1 includes resistors R03, R04, reed switches SW1, SW2, a power storage device (power storage element) Cs, and a Zener diode ZD1.

As the power storage device Cs, for example, a high-capacity super capacitor or an electric double-layer capacitor is used so that the device can store a relatively large amount of power. It is a matter of course that a secondary battery may be used as the power storage device Cs in place of a capacitance type device.

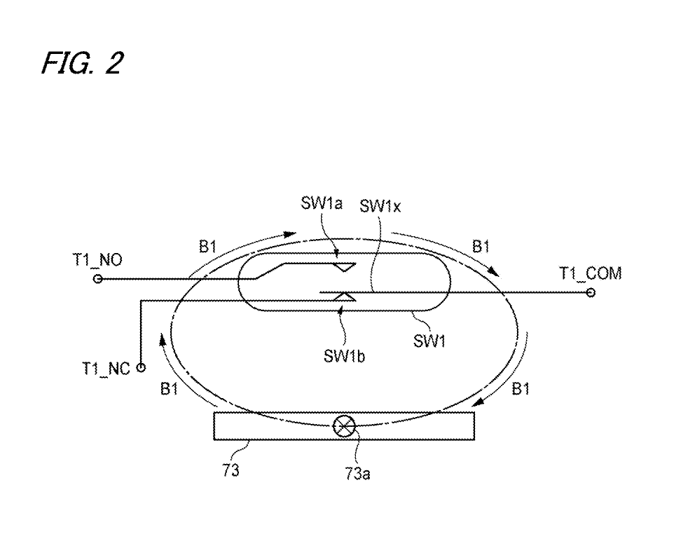

FIG. 2 shows Configuration example (1) of the vicinity of the reed switch SW1. The reed switch SW2 is configured in a similar manner as the configuration of FIG. 2. The reed switches SW1, SW2 constitute the magnetic switch circuit. As shown in FIGS. 1 and 2, each of the reed switches SW1, SW2 has a “c contact” type changeover contact. Namely, the reed switch SW1 has a normally open contact SW and a normally closed contact SW1b, and the reed switch SW2 has a normally open contact SW2a and a normally closed contact SW2b. In the embodiment, the side of the contacts SW1a, SW2a of the reed switches SW1, SW2 constitutes the first magnetic switch circuit, and that of the contacts SW1b, SW2b of the reed switches SW1, SW2 constitutes the second magnetic switch circuit.

When the reed switch SW1 is OFF, the contact SW is opened, and the contact SW1b is closed. When the reed switch SW1 is switched to ON, the contact SW is opened, and then the contact SW is closed. When the reed switch SW1 is switched to OFF, the contact SW is opened, and then the contact SW is closed. Therefore, a state where the two contacts SW1a, SW1b are simultaneously closed does not occur.

When the reed switch SW2 is OFF, similarly, the contact SW2a is opened, and the contact SW2b is closed. When the reed switch SW2 is switched to ON, the contact SW2b is opened, and then the contact SW2a is closed. When the reed switch SW2 is switched to OFF, the contact SW2a is opened, and then the contact SW2b is closed. Therefore, a state where the two contacts SW2a, SW2b are simultaneously closed does not occur.

A normally-open side terminal T1_NO which is connected to the contact SW1a of the reed switch SW1 is connected to the positive input-side terminal 13 via the resistor R03 and a high-voltage input-side line 71. A terminal of the contact SW2a of the reed switch SW2 is connected to the negative input-side terminal 14 via the resistor R04 and a high-voltage input-side line 72.

The power storage device Cs is connected between a common terminal 76 (T1_COM) which is common to the contacts SW1a, SW1b, and a common terminal 77 which is common to the contacts SW2a, SW2b. The Zener diode ZD1 is connected in parallel to the power storage device Cs. The Zener diode ZD1 is disposed for overvoltage protection of the power storage device Cs.

A normally-closed side terminal T1_NC which is connected to the contact SW1b of the reed switch SW1 is connected to the input of the power source unit 30 on the side of the diode D22, via an output-side line 74. A terminal of the contact SW2b is connected to a ground electrode 15 via an output-side line 75.

As shown in FIG. 2, each of the reed switches SW1, SW2 in the electric power storage apparatus 70 is placed at a position which is in proximity to a high-voltage bus bar (high-voltage conducting path) 73. Namely, the ON/OFF states of the reed switches SW1, SW2 are switched depending on the existence/nonexistence of the DC magnetic field generated from the high-voltage bus bar 73.

In the example shown in FIG. 2, it is assumed that, as indicated by a current direction 73a, a current directed from above to below flows as a charging current through the high-voltage bus bar 73 which is placed along an axis that is directed perpendicular to the sheet of the figure. Therefore, the charging current causes a magnetic field to be generated in the periphery of the high-voltage bus bar 73, and a magnetic flux B1 in the direction indicated by the arrows is generated. The magnetic flux B1 crosses the reed switch SW1 which is placed in the vicinity of the bus, and therefore the reed of the reed switch SW1 is magnetized. The resulting magnetic attraction force causes a reed movable portion SW1x to elastically deform, and the states of the contacts SW1a, SW1b are switched.

When the energization of the high-voltage bus bar 73 is ceased, the magnetic field and magnetic flux B1 in the periphery of the high-voltage bus bar 73 vanish. Therefore, the magnetization of the reed switch SW1 is canceled, and the contacts SW1a, SW1b are returned to the respective normal states by the elasticity of the reed. This is applicable also to the reed switch SW2.

The high-voltage bus bar 73 is disposed as a part of a positive power supply line through which the electric motor MOT and on-vehicle DC high-voltage power source 50 that are shown in FIG. 1 are connected to each other. When the on-vehicle DC high-voltage power source 50 is charged, i.e., when the electric power supplied from the electric motor MOT functioning as a generator, or the external equipment can be used, therefore, a direct current flows through the high-voltage bus bar 73.

Therefore, each of the reed switches SW1, SW2 is automatically switched to ON by the influence of the DC magnetic field generated from the high-voltage bus bar 73. In this case, the contacts SW1b, SW2b are opened, and the contacts SW1a, SW2a are then closed. Therefore, a current path for supplying an electric power to the power storage device Cs is formed by the closing of the contacts SW1a, SW2a. Then, the power storage device Cs stores the supplied power.

When the charging of the on-vehicle DC high-voltage power source 50 is ended, no current flows through the high-voltage bus bar 73. Therefore, the DC magnetic field which is generated from the high-voltage bus bar 73 vanishes, and each of the reed switches SW1, SW2 is automatically switched to OFF. In this case, the contacts SW1a, SW2a are opened, and then the contacts SW1b, SW2b are closed. Consequently, the power storage device Cs is cut off from the high-voltage circuit on the input side, and connected to the circuit on the output side, i.e., the power source unit 30 by the output-side lines 74, 75. In this state, the electric power stored in the power storage device Cs can be introduced into the power source unit 30 via the diode D22.

One of important matters in the electric power storage apparatus 70 is that the electric power which is to be used in the low-voltage circuit is introduced from the high-voltage circuit without using the low-voltage power source, and stored in the power storage device Cs. Another important matter is that the high-voltage circuit on the side of the input of the power storage device Cs is electrically isolated from the low-voltage circuit on the side of the output. The reed switches SW1, SW2 disposed in the electric power storage apparatus 70 attain these objects.

Namely, the contacts SW1a, SW1b of the reed switch SW1 isolate the high-voltage input-side line 71 from the output-side line 74, and the contacts SW2a, SW2b of the reed switch SW2 isolate the high-voltage input-side line 72 from the output-side line 75. Moreover, the ON/OFF states of the reed switches SW1, SW2 are switched mechanically and automatically depending on the existence/nonexistence of the magnetic field which is generated from the high-voltage bus bar 73. Therefore, it is not required to dispose a special control circuit. Consequently, it is not necessary to lay a low-voltage circuit for supplying a low-voltage power to such a control circuit, from a low-voltage battery of 12 [V] to the on-vehicle DC high-voltage power source 50 or the vicinity of the high-voltage bus bar 73, with the result that the high-voltage circuit can be isolated from the low-voltage circuit. Moreover, also a special electric source power for control is not necessary.

### <Modification (1) of Electric Power Storage Apparatus 70>

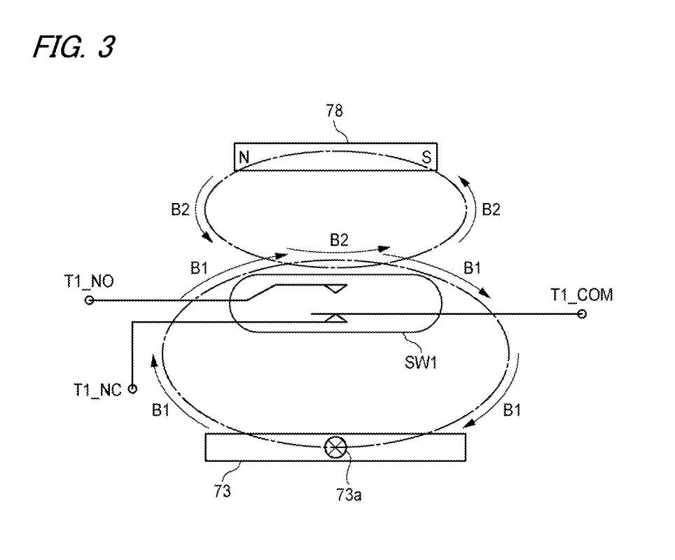

FIG. 3 shows Configuration example (2) of the vicinity of the reed switch SW1. The reed switch SW2 is configured in a similar manner as the configuration of FIG. 3.

In the configuration shown in FIG. 2, the ON/OFF states of the reed switches SW1, SW2 are switched depending on whether a current flows through the high-voltage bus bar 73 or not, and hence a control reflecting the difference in direction of the current cannot be performed. Therefore, a path in which, for example, the charging current in the direction flowing into the battery, and the discharging current in the direction flowing from the battery coexist cannot be used as the path for the high-voltage bus bar 73 that is used by the electric power storage apparatus 70.

The electric power storage apparatus 70 of the configuration of Modification (1) shown in FIG. 3 has a function of enabling an operation reflecting the difference in current direction to be performed. Even in the case where the high-voltage bus bar 73 is placed in the path in which the charging current in the direction flowing into the battery, and the discharging current in the direction flowing from the battery coexist, only when, for example, the current flows into the battery, i.e., the battery is charged by an external power source or a regenerative power, therefore, the contacts SW1a, SW2a can be turned ON, the power storage device Cs can be charged, and charges can be introduced.

Namely, the configuration shown in FIG. 3 is different from that shown in FIG. 2 in that a permanent magnet (magnetic field generating member) 78 is added. As shown in FIG. 3, the permanent magnet 78 is placed in the vicinity of the reed switch SW1. The DC magnetic field generated by the permanent magnet 78 causes a magnetic flux B2 to cross the reed switch SW1. In the case where the two reed switches SW1, SW2 are placed respectively at positions which are close to each other, the single permanent magnet 78 can be shared by the two reed switches SW1, SW2.

Also in the configuration shown in FIG. 3, when a current flows through the high-voltage bus bar 73, the current causes a DC magnetic field to be generated, and the magnetic flux B1 crosses the reed switch SW1. In the configuration shown in FIG. 3, therefore, the reed switch SW1 is affected by the composite magnetic field of the DC magnetic field of the permanent magnet 78, and that caused by the current flowing through the high-voltage bus bar 73.

In the example shown in FIG. 3, for example, the direction of the magnetic flux B1 coincides with that of the magnetic flux B2 in the vicinity of the reed switch SW1, and therefore the magnetic fluxes are added to each other, so that the composite magnetic field is enhanced. By contrast, in the case where a current in the direction opposite to the current direction 73a, i.e., the discharging current flows through the high-voltage bus bar 73, the direction of the magnetic flux B1 is opposite to that in the state shown in FIG. 3, the direction of the magnetic flux B1 is opposite to that of the magnetic flux B2 in the vicinity of the reed switch SW1, and the magnetic fields cancel each other, so that the composite magnetic field is weakened.

Namely, the intensity of the composite magnetic field which affects the reed switch SW1 is changed depending not only on the energization/deenergization of the high-voltage bus bar 73, but also on the energization direction. Therefore, the direction of the energization in the high-voltage bus bar 73 can be reflected in the conditions for the operation of switching the ON/OFF state of the reed switch SW1. For example, an operation may be performed so that, when a current of a predetermined or higher level flows through the high-voltage bus bar 73 in the direction along which the battery is charged, the reed switch SW1 is switched to ON, and, when a current flows through the high-voltage bus bar 73 in the direction along which the battery is discharged, the reed switch SW1 maintains the OFF state.

The actual electric power storage apparatus 70 can be designed so that the electric power storage apparatus 70 is caused to operate in accordance with one of the following two kinds of Conditions (1) and (2), depending on, for example, the characteristics of the employed permanent magnet 78, or the adjustment of the distance between the permanent magnet 78 and the reed switch SW1.

(1) In the case where the permanent magnet 78 generates a relatively weak magnetic field, the magnetic field due to the permanent magnet 78 is insufficient to cause the reed switch SW1 to turn ON. Therefore, the reed switch SW1 operates in the following manner depending on the energization state of the high-voltage bus bar 73.

When the bus bar is not energized: SW1 is turned OFF.

When the bus bar is forwardly energized (charged): the composite magnetic field is enhanced due to the addition of the fluxes B1, B2, and therefore the reed switch SW1 is turned ON.

When the bus bar is reversely energized (discharged): the composite magnetic field is weakened due to the mutual cancellation of the fluxes B1, B2 is decreased, and therefore the reed switch SW1 is turned OFF.

(2) In the case where the intensity of the magnetic field generated by the permanent magnet 78 is sufficiently high, the reed switch SW1 can be turned ON simply by the magnetic field due to the permanent magnet 78. Therefore, the reed switch SW1 operates in the following manner depending on the energization state of the high-voltage bus bar 73.

When the bus bar is not energized: SW1 is turned ON.

When the bus bar is forwardly energized (charged): the composite magnetic field is enhanced due to the addition of the fluxes B1, B2, and therefore the reed switch SW1 is turned ON.

When the bus bar is reversely energized (discharged): the composite magnetic field is weakened due to the mutual cancellation of the fluxes B1, B2, and therefore the reed switch SW1 is turned OFF.

Even in the case where the apparatus operates under any of Conditions (1) and (2) above, the ON/OFF state of the reed switch SW1 can be switched depending on the direction of the current flowing through the high-voltage bus bar 73. Namely, a bias is applied in a specific direction from the influence of the DC magnetic field generated by the permanent magnet 78, and therefore the difference in direction of the current flowing through the high-voltage bus bar 73 can be reflected in the operation of the reed switch SW1.

### <Modification (2) of Electric Power Storage Apparatus 70>

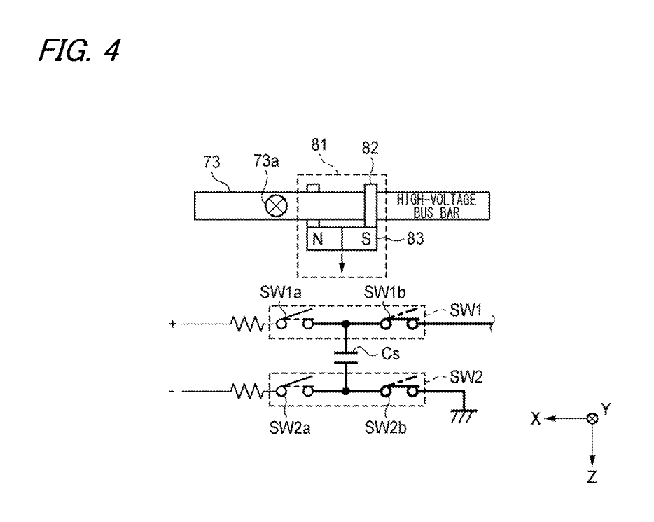

FIG. 4 shows Configuration example (3) of the vicinity of the reed switch SW1.

Also the electric power storage apparatus 70 of the configuration of Modification (2) shown in FIG. 3 has the function of enabling an operation reflecting the difference in current direction to be performed. Even in the case where the high-voltage bus bar 73 is placed in the path in which the charging current in the direction flowing into the battery, and the discharging current in the direction flowing from the battery coexist, only when the current flows into the battery, therefore, the reed switches SW1, SW2 can be switched, and the electric power can be recovered and stored.

In the configuration shown in FIG. 4, a movable portion 81 is disposed in the high-voltage bus bar 73. The movable portion 81 includes a permanent magnet 83 which is supported by a supporting member 82 in a state where the magnet is movable in the Z-direction. In the deenergization state of the high-voltage bus bar 73, the permanent magnet 83 is located at a specific position by the force of an elastic member which is not shown. In the high-voltage bus bar 73, a current flows in the Y-direction or the direction opposite thereto. The permanent magnet 83 generates a DC magnetic field in the X-direction which is perpendicular to the Y-direction. The reed switches SW1, SW2 are placed in the vicinity of the permanent magnet 83 so as to be opposed to the magnet.

When a current flows in the Y-direction through the high-voltage bus bar 73, therefore, a force is generated in the Z-direction which is perpendicular to the Y- and X-directions, according to Fleming's left-hand rule. The position of the permanent magnet 83 is moved in the Z-direction by the force. The distances between the permanent magnet 83 and the reed switches SW1, SW2 are changed by the Z-direction movement, and therefore the strength of the magnetic field which affects the reed switches SW1, SW2 is changed.

When the direction of the current flowing through the high-voltage bus bar 73 is reversed, the permanent magnet 83 is moved in the direction opposite to the Z-direction. Namely, the position of the permanent magnet 83 is changed depending on the energization/deenergization of the high-voltage bus bar 73, and the energization direction. In accordance with the change, also the strength of the magnetic field which affects the reed switches SW1, SW2 is changed.

When the permanent magnet 83 is moved to a proximal position, each of the reed switches SW1, SW2 shown in FIG. 4 is turned ON, and, when the permanent magnet is returned to the distal position, the switch is turned OFF. Therefore, when the charging current in the direction along which the battery is charged flows through the high-voltage bus bar 73, for example, the permanent magnet 83 approaches the reed switches SW1, SW2, the reed switches SW1, SW2 are turned ON, and the electric power supplied from the high-voltage circuit is stored in the power storage device Cs in the electric power storage apparatus 70. When the discharging current in the direction along which the battery is discharged flows through the high-voltage bus bar 73, the permanent magnet 83 separates from the reed switches SW1, SW2, the reed switches SW1, SW2 are turned OFF, and therefore the power storage device Cs is isolated from the high-voltage circuit.

In the case where the configuration shown in FIG. 4 is used, even when the DC magnetic field due to a current flowing through the high-voltage bus bar 73 is relatively weak, the reed switches SW1, SW2 are caused to surely operate, by the DC magnetic field generated by the permanent magnet 83, and a change of the position of the permanent magnet 83.

Next, a configuration example of the ground fault measurement circuit 10 will be described.

As shown in FIG. 1, a detection capacitor C1 which functions as a flying capacitor is disposed in the ground fault measurement circuit 10.

In order to control charging and discharging of the detection capacitor C1, four switching devices S1 to S4 are disposed in the periphery of the capacitor. Moreover, a switching device Sa is disposed in order to sample the voltage for measurement. Each of the switching devices S1 to S4 and Sa is a switch which can switch the closing/opening (ON/OFF of conduction) state of the contact by a control of an isolated signal, such as an optical MOSFET.

One end of the switching device S1 is connected to the positive input-side terminal 13 via a resistor R01, and the other end to a wiring 41. One end of the switching device S2 is connected to the negative input-side terminal 14 via a resistor R02, and the other end to a wiring 42 via a resistor R2.

One end of the switching device S3 is connected to a wiring 43, and the other end to a wiring 45. One end of the switching device S4 is connected to a wiring 42, and the other end to the ground electrode 15 via a resistor R4.

The negative terminal of the detection capacitor C1 is connected to the wiring 42. The positive terminal of the detection capacitor C1 is connected to the wiring 41 via a series circuit which is configured by a diode D1 and a resistor R1. The positive terminal of the detection capacitor C1 is connected also to the wiring 43 via a series circuit which is configured by a diode D3 and a resistor R5, and further to the wiring 43 via a diode D2. The diode D2 is connected in a polarity in which energization in a direction directed from the wiring 43 toward a wiring 44 is allowed, and the diode D3 is connected in a polarity in which energization in a direction directed from the wiring 44 toward the wiring 43 is allowed.

In order to discharge the charges stored in the detection capacitor C1, the wiring 44 may be grounded via a special switch and resistor which are not shown. When components having a relatively small resistance are used as the resistors R3 to R5, however, such a special discharge circuit may be omitted.

A microcomputer (CPU) 11 executes preinstalled programs to perform various controls necessary for the ground fault measurement circuit 10. Specifically, the microcomputer 11 individually controls the switching devices S1 to S4 to control the charging/discharging of the detection capacitor C1 Moreover, the microcomputer 11 receives an analog level corresponding to the charging voltage of the detection capacitor C1, from an analog port AD1 via a wiring 46, and performs a calculation based on the input level, thereby knowing the ground fault resistances RLp, RLn.

The switching device Sa is connected between the wirings 45, 46. At a certain measurement timing, the switching device Sa is closed for a short time period, and a signal which appears in the wiring 45 is sampled. Namely, the voltage level of the measurement target is held by a capacitor 22 connected to the input of the microcomputer 11.

Moreover, an electric power is supplied from the power storage device Cs of the electric power storage apparatus 70 via the output-side line 74 and the diode D22, whereby the electric power required by the power source unit 30 can be ensured. The diode D22 blocks a current in the reverse direction, and therefore charges stored in the capacitor 31 can be prevented from reversely flow to cause discharging.

In the system shown in FIG. 1, the logic DC power supply voltage Vcc which is output to the output terminal 32b by the power source unit 30 is supplied as the electric source power to logic circuits in the ground fault measurement circuit 10, such as the microcomputer 11. Therefore, stored charges in the power storage device Cs can be introduced into the power source unit 30, and supplied to the side of the ground fault measurement circuit 10 as the power source.

The basic operation of the ground fault measurement circuit 10, and the principle of the measurement of the ground fault resistance are similar to those of the prior art disclosed in Patent Literatures 1 to 3 and the like, and therefore their description is omitted.

### <Advantages of Electric Power Storage Apparatus 70>

In the case where a charging current flows into the on-vehicle DC high-voltage power source 50, the electric power storage apparatus 70 shown in FIG. 1 can automatically detect the flow, receive the electric power, and cause the electric power to be stored in the power storage device Cs. Moreover, the reed switches SW1, SW2 are used in the switch circuit for isolating the high-voltage circuit from the low-voltage circuit. Therefore, an automatic switching operation can be realized without causing special power consumption. Moreover, it is not necessary to use an expensive switching device such as an optical MOSFET.

In the case where the configuration shown in FIG. 3, or that shown in FIG. 4 is employed, only when a charging current directed to a specific direction flows through the high-voltage bus bar 73, the reed switches SW1, SW2 can be automatically switched to ON to perform the operation of storing the electric power. Therefore, even the high-voltage bus bar 73 that is placed in the path in which the charging and discharging currents coexist can be used in the current detection.

Similarly with the ground fault measurement circuit 10 shown in FIG. 1, an apparatus for measuring the power source voltage may be configured by using the detection capacitor C1 which is a flying capacitor. Also in the case where such an apparatus is used, it is possible to configure a system which is similar to the ground fault measurement circuit 10 shown in FIG. 1.

Although, in the electric power storage apparatus 70 shown in FIG. 1, the reed switches SW1, SW2 of the “c contact” type are used, the contacts SW1a, SW1b, SW2a, SW2b may be independent reed switches, respectively. In this case, in order to isolate the high-voltage circuit and the low-voltage circuit from each other, careful attention must be paid so that the two contacts SW1a, SW1b are not simultaneously closed. This is applicable also to the contacts SW2a, SW2b.

In the configuration shown in FIG. 3, the positional relationships among the high-voltage bus bar 73, the reed switch SW1, and the permanent magnet 78, the polarity direction of the permanent magnet 78, the directions of the magnetic fluxes B1, B2, and the like can be changed as required. In the configuration shown in FIG. 4, the relationship between the current direction 73a of the high-voltage bus bar 73, and the direction of the magnetic field of the permanent magnet 83 can be changed.

The electric power which is output as the logic DC power supply voltage Vcc by the power supply unit 30 is assumed to be used, for example, for the following purposes, in addition to the above-described use by the ground fault measurement circuit 10 itself.

(1) The power is used as power sources for various sensors.
(2) The power is used as power sources for various electronic control units (ECUs) mounted on the vehicle.
(3) The power is used as power sources for driving relays, various electric components, various loads, and the like.
(4) The power is used as power sources for enabling wireless apparatuses to transmit and receive signals by using radio waves or the like. In the case where the user operates a smart key in a vehicle, for example, a situation where the ignition switch of the vehicle is OFF is supposed. When the power supply unit 30 is used, however, the necessary electric power can be easily ensured.

In the above-described embodiment, the on-vehicle DC high-voltage power source 50 includes a battery of about 100 to 200 [V] as a driving source for enabling a vehicle such as an electric vehicle or a hybrid vehicle to generate a propulsion force, and is used in the high-voltage circuit, and a usual 12-[V] battery is used in the low-voltage circuit. The invention is not limited to this. In a conventional gasoline vehicle or the like, in addition to a usual 12-[V] battery, another battery of 36 to 48 [V] for supplying a power to vehicle loads is sometimes disposed from the viewpoint of efficiency of the power distribution. The invention may be applied also to a case where the other battery is used in the high-voltage circuit, and the usual 12-[V] battery is used in the low-voltage circuit.

In other words, in the case where a vehicle has two or more kinds of batteries, and the higher battery voltage is about two or more times higher than the lower battery voltage, the invention may be applied to a configuration in which a circuit including the battery of the higher voltage is used as the high-voltage circuit, and that including the battery of the lower higher voltage is used as the low-voltage circuit.

In the above-described embodiment, moreover, the contacts SW1a, SW2a are disposed on the side of the on-vehicle DC high-voltage power source 50 with respect to the power storage device Cs, and the contacts SW1b, SW2b are disposed on the side of the power source unit 30. As another configuration example, although the use efficiency of charges is lower than that in the above-described embodiment, the reed switches may be configured so that the contacts SW1a, SW2a are disposed on the side of the on-vehicle DC high-voltage power source 50, and no contact is disposed on the side of the power source unit 30. In this case, a voltage dropping element is connected downstream the contact SW1a.

In addition to the above-described embodiment, a configuration may be employed in which the current value at which the states of the reed switches are changed may be set to a value other than zero. In the above-described embodiment, when a current begins to flow through the high-voltage bus bar 73, or when the direction of a current flowing through the high-voltage bus bar 73 is changed, namely, the states of the reed switches are changed. Alternatively, the states of the reed switches may be changed in the case where the value of a current flowing through the high-voltage bus bar 73 reaches from zero to a predetermined threshold, that where the direction of the current is changed, and then the value of the current reaches to a threshold, or that where the value of the current becomes smaller than a threshold immediately before the direction of the current is changed. In the invention, namely, the operation of switching the connection and disconnection states based on the magnetic field generated by a current flowing through the high-voltage bus bar which is electrically connected to the battery circuit includes all of the above-described cases.

As described above, according to the invention, it is possible to provide an electric power storage apparatus in which it is not required to, in order to control the operation of the apparatus itself, supply a power source power from a low-voltage circuit, and therefore the low-voltage circuit can be isolated from a high-voltage circuit in the vicinity of a main battery.

What is claimed is:

1. An electric power storage apparatus wherein
the apparatus includes:
a power storage element which can store an electric power supplied from a battery circuit of a vehicle; and
a magnetic switch circuit which can be switched between connection and disconnection states of the battery circuit and the power storage element, and,
when a magnetic field is generated by a current flowing through a high-voltage conducting path that is electrically connected to the battery circuit, the magnetic switch circuit is switched to the connection state.

2. An electric power storage apparatus wherein
the apparatus includes:
a power storage element which can store an electric power supplied from a battery circuit of a vehicle;
a first magnetic switch circuit which can be switched between connection and disconnection states of the battery circuit and the power storage element; and
a second magnetic switch circuit which can be switched between connection and disconnection states of the power storage element and an external low-voltage circuit,
when one of the first magnetic switch circuit and the second magnetic switch circuit is in the connection state, the other magnetic switch circuit is in the disconnection state, and the connection and disconnection states are switched based on a magnetic field which is generated by a current flowing through a high-voltage conducting path that is electrically connected to the battery circuit.

3. The electric power storage apparatus according to claim 2, wherein,
in a case of a magnetic field which is generated by a current in a direction along which the current flows into the battery circuit, the first magnetic switch circuit is in the connection state, and the second magnetic switch circuit is in the disconnection state, and,
in a case of a magnetic field which is generated by a current in a direction along which the current flows from the battery circuit, the first magnetic switch circuit is in the disconnection state, and the second magnetic switch circuit is in the connection state.

4. The electric power storage apparatus according to claim 2, wherein
the apparatus further includes a magnetic field generating member which is placed in a vicinity of the first and second magnetic switch circuits, and which provides a predetermined DC magnetic field for the first and second magnetic switch circuits, and,
in the first and second magnetic switch circuits, the connection and disconnection states are switched according to a degree of an influence of the DC magnetic field generated by the magnetic field generating member.

5. The electric power storage apparatus according to claim 2, wherein
the external low-voltage circuit constitutes a part of a detection circuit for detecting a state relating to the battery circuit, the power storage element is connected to the detection circuit, and
the electric power stored in the power storage element is used for driving the detection circuit.
